(19) United States
(12) Patent Application Publication
(10) Pub. No.: US 2024/0178679 A1
(43) Pub. Date: May 30, 2024

(54) CONTROLLING REVERSE IN-RUSH CURRENT FOR VEHICLE CHARGERS

(71) Applicant: Rivian IP Holdings, LLC, Plymouth, MI (US)

(72) Inventors: Vishnu Mohan, Long Beach, CA (US); Zahra Mohajerani, Los Angeles, CA (US)

(21) Appl. No.: 18/059,578

(22) Filed: Nov. 29, 2022

(51) Int. Cl. H02J 7/00; B60L 53/20; B60L 53/62; G01R 19/165; H02J 7/34; H02M 3/335

(52) U.S. Cl. CPC H02J 7/00304; B60L 53/20; B60L 53/62; G01R 19/16576; H02J 7/007182; H02J 7/345; H02M 3/33573; B60L 2210/30; B60L 2210/40; B60L 2270/20; H02J 2207/20

(57) ABSTRACT

Controlling reverse in-rush current for vehicle chargers is provided. A system can include a controller to determine a first value of voltage. The voltage can be of or associated with a DC link of a charger to output power to a battery of an electric vehicle. The controller can detect an in-rush current from the battery to the charger. The detection can be responsive to the first value of voltage at the DC link being greater than a reference value of voltage established for the DC link.

### INTRODUCTION

Electric systems, such as electric vehicles or chargers, can include a node having a variable voltage. The various electrical systems can be configured to interconnect.

### SUMMARY

This disclosure is generally directed to controlling reverse in-rush current when a charger is connected to a vehicle battery. For example, this technology can provide a controller that senses or detects a voltage in a direct current (“DC”) link of the charger. The controller can compare this voltage with a reference voltage, and then increase an output voltage of the charger based on the comparison. By increasing or otherwise adjusting the output voltage of the charger based on the comparison, the controller of this technology can prevent the reverse in-rush current from the vehicle battery when DC contactors are closed to connect the charger to the vehicle battery.

At least one aspect is directed to a system. The system can include a controller. The controller can include circuitry or one or more processors coupled with memory. The controller can be configured to determine a first value of voltage at a direct current (“DC”) link in a charger configured to output power to a battery of an electric vehicle. The controller can be configured to detect an in-rush current from the battery to the charger. The detection can be in response to the first value of voltage at the DC link being greater than a reference value of voltage established for the DC link.

At least one aspect is directed to a system. The system can include a controller. The controller can be configured to determine a first value of voltage at a DC link in a charger configured to output power to a battery via a capacitor. The controller can be configured to control voltage at the capacitor. The detection can be responsive to a comparison of the first value of voltage at the DC link with a reference value of voltage established for the DC link.

At least one aspect is directed to a method. The method can performed by a controller. The controller can include circuitry or one or more processors coupled with memory. The method can include determining a first value of voltage at a DC link in a charger configured to output power to a battery via a capacitor. The method can include controlling voltage at the capacitor. The voltage can be controlled responsive to a comparison of the first value of voltage at the DC link with a reference value of voltage established for the DC link.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts a block diagram of an example system for controlling reverse in-rush current for a charger, in accordance with some aspects.

FIG. 2 depicts an example electric vehicle coupled to a charger, in accordance with some aspects.

FIG. 3 depicts an example circuit for controlling reverse in-rush current, in accordance with some aspects.

FIG. 4 depicts example voltages of a DC link charging an electric vehicle over time, in accordance with some aspects.

FIG. 5 depicts an example flow diagram of a method for controlling reverse in-rush current, in accordance with some aspects.

FIG. 6 depicts a flow diagram of an example method for controlling reverse in-rush current, in accordance with some aspects.

FIG. 7 is a block diagram illustrating an architecture for a computer system that can be employed to implement elements of the systems and methods described and illustrated herein.

### DETAILED DESCRIPTION

Following below are more detailed descriptions of various concepts related to, and implementations of, methods, apparatuses, and systems of controlling reverse in-rush current. The various concepts introduced above and discussed in greater detail below may be implemented in any of numerous ways.

The present disclosure is directed to controlling reverse in-rush current. For example, this technology can be employed for DC chargers having dual active bridges to charge batteries of electric vehicles. A pre-charge session can include a time after connecting a battery to a charger. During this time, the charger can establish communication between a charger and the battery. The charger can close a contact between the battery and the charger to connect the battery to the charger. If the battery voltage exceeds an output voltage in a charging circuit of the charger, the charging circuit of the charger can receive a reverse in-rush current. A reverse in-rush current into the charging circuit of the charger can impact the performance of the charging session, the duration of the charging session, or battery performance.

The disclosed solutions have a technical advantage of faster reliable detection of reverse in-rush current from a battery. For example, a controller can detect an in-rush current by monitoring a voltage sensor of a DC link input circuit to detect a reverse in-rush current with a higher reliability than by monitoring a current sensor which is proximal to switching noise or other environmental influences of a charger output circuit. Filters to damp or suppress errant signals or noise can be applied to the current sensor, which can increase an amount of time to detect an reverse in-rush current. A controller can detect the in-rush current more quickly by monitoring the voltage sensor of the DC link input circuit than the filtered output of the current sensor of the charger output circuit, according to some aspects.

This technical solution can include a controller to detect an in-rush current in a charging circuit of a DC charger. The controller can detect the in-rush current using a voltage sensor to determine a voltage of the DC link in the charging circuit of the charger. For example, the voltage sensor can be isolated from the output of the charging circuit by a DC to DC circuit, such as a dual active bridge (“DAB”) circuit. Such a disposition can be referred to as an output of the DC link. One or more capacitors in the charging circuit can maintain a desired voltage, and store power during the switching of circuit elements to deliver a DC signal to a battery. For example, an output capacitor can be disposed at or proximate to the output of the charging circuit. A DC link capacitor can be disposed at or proximate to the voltage sensor. A controller of the charger can detect a voltage of the DC link capacitor. The controller can establish a reference voltage level. For example, the controller can establish a DC link reference voltage of 800 volts. The controller can detect a rise in the voltage of the DC link following a connection of a battery to the charger. For example, the controller can sense a DC link input circuit voltage of 810 volts. The increase in voltage can be a result of reverse in-rush from the battery to the charger. The controller can increase the reference voltage of the DC link to reduce or eliminate the reverse in-rush current from the battery to the charger. For example, the controller can increase the reference voltage to 810 volts, or another value such as 815 volts (e.g., to account for resistive or diode drops between the charger and the battery). The controller can thereafter charge the battery of the vehicle.

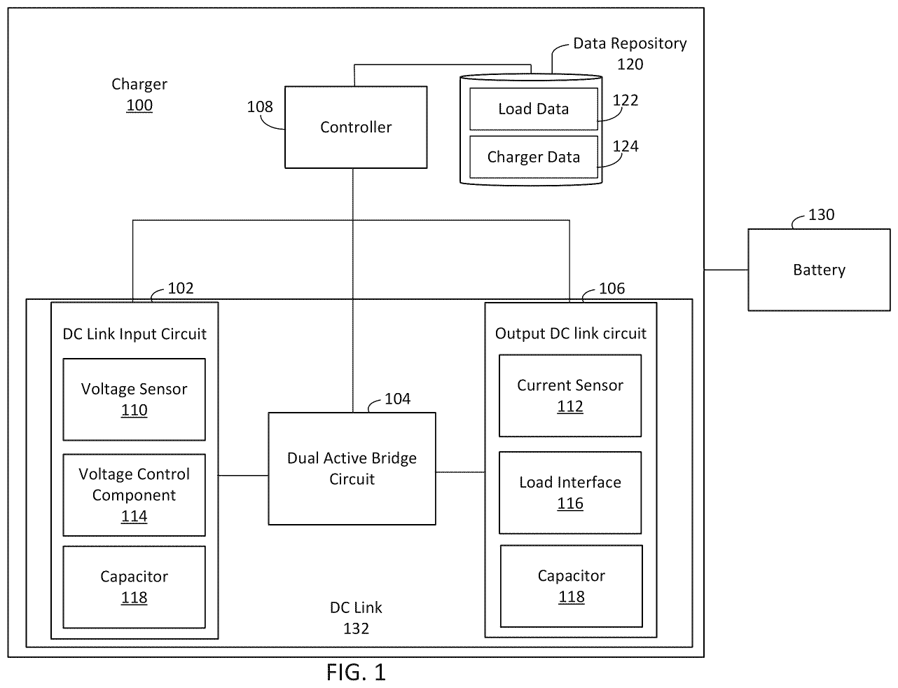

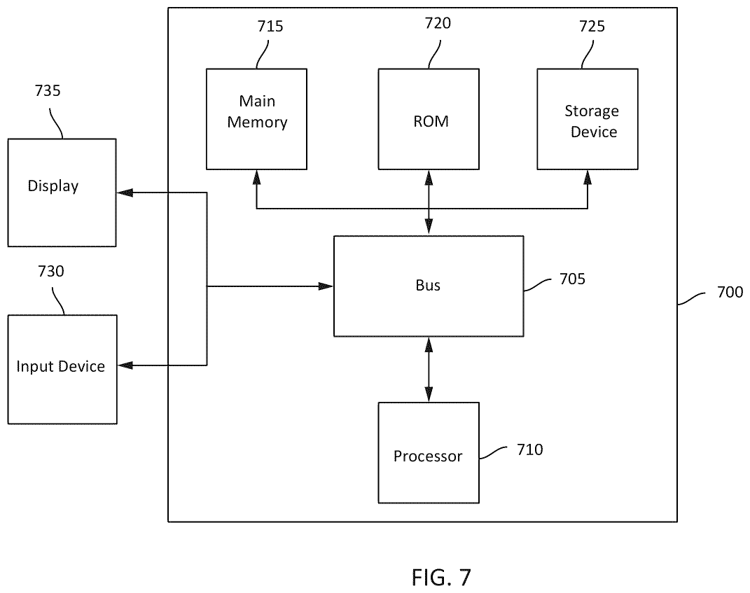

FIG. 1 depicts a block diagram of an example system for controlling reverse in-rush current for a charger 100, in accordance with some aspects. The charger 100 can include at least one DC link 132 including a DC link input circuit 102, dual active bridge circuit 104, or output DC link circuit 106, which can also be referred to as an output of the charger 100. The charger can include at least one controller 108 such as a charge controller 108, voltage sensor 110, current sensor 112, voltage control component 114, load interface 116, capacitor 118, or data repository 120. One or more components of the charger 100 (e.g., the controller 108) can include a processing unit or other logic device such as a programmable logic array engine, or module configured to communicate with the data repository 120 or database. The DC link input circuit 102, dual active bridge circuit 104, output DC link circuit 106, controller 108, voltage sensor 110, current sensor 112, voltage control component 114, load interface 116, or capacitor 118 can be separate components, a single component, or part of the charger 100. The charger 100 can include hardware elements, such as one or more processors, logic devices, or circuits. For example, the charger 100 can include one or more components or structures of functionality of computing devices depicted in FIG. 7.

The data repository 120 can include one or more local or distributed databases, and can include a database management system. The data repository 120 can include computer data storage or memory and can store one or more of load data 122 or charger data 124. The load data 122 can include information associated with a battery 130 or other load such as a capacity, a charging rate, a state of charge, a voltage, a unique identifier such as a VIN or a token, a battery type, or a temperature. The charger data 124 can include a voltage of the output DC link circuit 106, a charging rate, or a historical charging rate or charging output. For example, the charger data 124 can include a reference voltage for one or more electric vehicles.

The charger 100 can include at least one DC link input circuit 102 designed, constructed, or operational to interface between stages of a charger 100. For example, the DC link input circuit 102 can interface between alternating current (AC) or direct current (DC) charger stages. The DC link input circuit 102 can receive power from an input such as an energy grid, an energy storage device, or a renewable energy source such as a solar array. The DC link input circuit 102 can supply power to a DC to DC converter such as a DAB circuit 104.

The DC link input circuit 102 or other components of the charger 100 can include or interface with at least one voltage sensor 110 designed, constructed, or operational to detect, measure or infer a voltage of one or more components of a charger 100 or electric vehicle. For example, the voltage sensor 110 can be or include a comparator to compare a voltage to a known reference voltage, or a digital or analog input to correlate a voltage (e.g., a scaled portion of a voltage, such as a portion of a voltage divider circuit) to another voltage according to a resolution of the input. The voltage sensor 110 can be disposed at an output DC link circuit 106, or one or more intermediate components can segregate the voltage sensor 110 from the output DC link circuit 106. For example, a filtering component, isolation component, or DC to DC conversion component can segregate the voltage sensor 110 from the output DC link circuit 106 (e.g., a DAB circuit 104).

The voltage sensor 110 can provide a voltage or a value of voltage in volts. The value of voltage can be relative to a reference voltage, such as a ground, or a reference voltage (e.g., voltage of the DC link input circuit 102 or the output DC link circuit 106). The voltage sensor 110 can provide a voltage value or an indication of a value exceeding reference voltage. The voltage sensors 110 can be disposed across one or more portions of a DC link input circuit 102. For example, a DC link input circuit 102 can include a center tap, a positive leg 305, and a negative leg 310 such that the positive leg 305 and negative leg 310 can be combined to form a voltage greater than either of the positive leg 305 or negative leg 310 individually. The voltage sensor 110 can be disposed from the positive leg 305 to the negative leg 310, or a voltage sensor 110 can sense a voltage of each leg of the DC link input circuit 102.

The DC link input circuit 102 or other components of the charger 100 can include or interface with at least one voltage control component 114. The voltage control component 114 can include or interface with an input to the DC link input circuit 102 such as an inverter or a DC to DC converter. The voltage control component 114 can include or interface with an output of the DC link input circuit 102, such as the DAB circuit 104. For example, the voltage control component 114 can include an output to control the gates of a switching transistor of a DC circuit (e.g., a duty cycle thereof), to control a current limit of an AC to DC converter, or otherwise cause an adjustment to a voltage of either of the DC link input circuit 102 or the output DC link circuit 106. The voltage control component 114 can be or interface with the controller 108. For example, the controller 108 can provide a control signal to the voltage control component 114. The control signal can be a phase shifted control signal, a pulse width modulated (PWM) signal, an analog signal, or a digital signal such as a single-bit digital input or output or a symbol, character, or string. The control signal can indicate an absolute value (e.g., magnitude) of a desired voltage or a relative value of a desired voltage (e.g., an indication to increase or decrease a voltage). Responsive to a receipt of the control signal, the voltage control component 114 can cause an adjustment to a voltage. For example, the voltage control component 114 can increase or decrease a voltage of the DC link input circuit 102 or the output DC link circuit 106.

The DC link input circuit 102 or other components of the charger 100 can include or interface with at least one capacitor 118 designed, constructed, or operational to sink, source, or store energy. For example, the capacitor 118 can maintain a voltage. Upon a connection of a battery 130 to the charger 100, the charger 100 (e.g., via capacitor 118) can deliver energy (e.g., output power to the battery 130) based on a higher voltage of the capacitor 118 than the battery 130. However, if the voltage of the capacitor 118 is lower than the voltage of the battery 130, then the capacitor 118 may sink energy (e.g., receive power from the battery 130). For example, the capacitor 118 can deplete the state of charge of the battery 130. The capacitor 118 can include any number of constituent capacitors 118. The capacitor 118 can be disposed at an output of the charger 100, or another node of the charger 100. For example, the capacitor 118 can source or sink energy through one or more additional circuit elements, such as through the DAB circuit 104.

The charger 100 can include at least one DAB circuit 104 designed, constructed, or operational to convey energy between the DC link input circuit 102 and an output DC link circuit 106. The DAB circuit 104 can include a transformer to isolate an input and an output of the output DC link circuit 106. The DAB circuit 104 can include a step up, step down, or unitary transformer to control a voltage of the output DC link circuit 106. For example, the DAB circuit 104 can include a step down transformer having a windings ratio of about 1:2. The DAB circuit 104 can include switchable transistors to control a flow of current. For example, the DAB circuit 104 can vary a direction or magnitude of current flow according to a control signal. The DAB signal can receive a control signal from a controller 108. Various DC to DC circuits can be substituted for the DAB circuit 104. For example, the DAB circuit 104 can be substituted for a half-full bridge circuit, bidirectional fly-back circuit, LLC resonant converter, or another buck or boost DC converter.

The charger 100 can include at least one output DC link circuit 106 designed, constructed, or operational to monitor, filter, or regulate a voltage applied to a battery 130 (e.g., over the load interface 116). The output DC link circuit 106 can be configured for operation with an electric vehicle or otherwise to interface with an environment or user. For example, the output DC link circuit 106 can include filters or transient protection.

The output DC link circuit 106 or other components of the charger 100 can include at least one current sensor 112 designed, constructed, or operational to detect a current of the charger 100. The current sensor 112 can sense a current at an output of the charger 100 or an output of the DC link input circuit 102. The current sensor 112 can be a contact sensor or a non-contact sensor. For example, the current sensor 112 can be an inductive sensor, resistive sensor, or a hall effect sensor.

The current sensor 112 can include, interface with, or otherwise communicate with a filter. For example, a digital or analog filter can include a time average (e.g., integral), a time series, resistor-capacitor (RC), resistor-inductor-capacitor (RLC), or another filtering element. For example, the filter can insulate the current sensor 112 from interference from a load, such as an electrical vehicle or another aggressor signal. The filter can delay a detection of a transient such as an in-rush of current to the charger 100. An in-rush of current describes a flow of current incident to an electrical connection of the battery 130 and the charger 100. The in-rush can describe a flow of current from the charger 100 to the battery 130, or a reverse in-rush, a flow of current from the battery 130 to the charger 100. For example, an in-rush of current or a voltage rise of a capacitor 118 of the DC link input circuit 102 can be detected at the DC link input circuit 102 prior to, or with greater reliability than, a signal detected by the current sensor 112. The filter can be applied to a signal of the current sensor 112 at a point of sensing, or elsewhere. For example, the filter can be applied by the controller 108 upon receipt of a signal from the current sensor 112.

The output DC link circuit 106 can include or interface with at least one load interface 116 designed, constructed, or operational to connect a load such as a battery 130. The load interface 116 can include a plug or receptacle of the charger 100 to connect to an electric vehicle. The plug or receptacle can include one or more power or ground terminals or one or more data terminals (e.g., pins or sockets) to convey information. The data pins can interface between controllers, or other components of a battery 130. For example, a data terminal can include or interface with a jumper or resistor, such as a presence detection pin or an encoded value. The value can be indicative of a presence of a connection or a vehicle characteristic, such as a nominal or maximum voltage or charging current. The data terminal can receive an indication (e.g., from a controller of the battery 130, such as a controller of an electric vehicle).

The load interface 116 can include a wireless connection such as a Bluetooth or WiFi connection between a load, or a device associated therewith. The load interface 116 can receive load data 122 over a wired or wireless connection. For example, the load interface 116 can receive a vehicle identifier or load data 122 such as a nominal or measured voltage of a battery 130 of the electric vehicle.

The load interface 116 can include a switchable connection such as a relay (e.g., a solid state or mechanical relay). For example, the switchable connection can be closed, responsive to a detection of a presence of a battery 130. The switchable connection can be closed, responsive to an authentication of the electric vehicle. For example, the authentication can include a validation of a vehicle identify, vehicle type, charger type (e.g., adherence to a standard), identity of a user, an establishment of a communicative connection with the electric vehicle, or an associated controller (e.g., a mobile device of a user associated with the electric vehicle or an processor of the electric vehicle).

The charger 100 can include at least one controller 108 designed, constructed, or operational to control energy delivered to a load such as a battery 130. For example, the controller 108 can be or include a charge controller 108. The controller 108 can control a voltage of a DC link input circuit 102 which can, in turn, control the voltage of the output DC link circuit 106. The controller 108 can control the voltage responsive to load data 122, a detected voltage, a detected current, or a thermal measurement. The detected current can include a current magnitude or direction between the battery 130 and the charger 100. The detected voltage can include a voltage with reference to a ground or another reference. A current can be detected based on a measured voltage (e.g., a voltage-current relationship). For example, the detected voltage can be with respect to a reference voltage, and a current can be determined (e.g., inferred) therefrom. The controller 108 can detect a current which is higher or lower than a threshold. The threshold can be a threshold for a desired in-rush current, a desired charging current, or a protection mechanism.

The detected current can vary between a current detected by a current sensor 112 and a current delivered to the battery 130. Likewise, a voltage detected by the voltage sensor 110 can be different than a voltage delivered to the battery 130. For example, a charger 100 can include a converter (e.g., a DAB circuit 104) such that a detected current or voltage is disposed on a first side of the DAB circuit 104. The controller 108 can infer a voltage or current delivered to the battery 130 on a second, opposite side of the DAB circuit 104 based on the transformer coil ratio, phase shift control signal, or resistive losses therebetween.

The controller 108 can adjust a voltage to control the delivery of energy to a battery 130. For example, the controller 108 can establish a reference voltage level based on an estimated voltage level of the battery 130. The controller 108 can establish a fixed or variable first voltage. For example, the fixed reference voltage can be a fixed voltage of the DC link input circuit 102 of the charger 100. A variable voltage can vary with respect to a temperature, or other load data 122 or charger data 124. The controller 108 can establish a reference voltage level based on load data 122. For example, the controller 108 can establish a voltage to match a battery voltage, such as based on a presence of the load, or other load data 122. For example, the controller 108 can establish various voltages for various electric vehicles, battery types, or states of charge. The controller 108 can detect a voltage of a DC link input circuit 102 from which a voltage of a battery 130 can be inferred after a connection thereto. For example, the controller 108 can detect a voltage different than the established voltage (e.g., higher or lower). The controller 108 can adjust a voltage to match the voltage of the battery 130 or otherwise reduce a difference of the voltage therebetween. The controller 108 can adjust a voltage to cause energy to be exchanged with the battery 130. For example, the controller 108 can adjust a voltage to cause a charger 100 to deliver energy to the battery 130. The controller 108 can vary the voltage to control a target charging current. The controller 108 can adjust the voltage responsive to one or more detected voltages or currents of an associated circuit. For example, an adjustment to match a voltage of a battery 130 can be based on a voltage detected by a voltage sensor 110, and a subsequent adjustment to charge the battery 130 can be based on a current detected by a current sensor 112.

The controller 108 can determine a duration for which a value of a voltage at the DC link 132 (e.g., the DC link input circuit 102) is greater than the reference value established for the DC link 132. For example, the controller 108 can determine a duration of one second. The controller 108 can trigger a flag responsive to the detected duration which is greater than or equal to the threshold. For example, the flag can provide an alert via a human-machine interface device such as an LED, an audible alert, email, text message, or an application notification. The flag can cause an alert to be conveyed to a user of the charger, a maintenance technician, or be stored. The controller 108 can, responsive to the flag, modify the operation of the charger 100. For example, the controller 108 can terminate current flow from the charger 100, such as by opening a switchable connection or shifting the phase of a control signal to the DAB circuit 104 to cause the DAB circuit 104 to block current flow. The controller 108 can terminate current flow from a portion of the charger 100. For example, the controller can terminate or otherwise limit current flow from a DC portion of the charger, and can maintain AC charging.

The controller 108 can adjust the voltage periodically or in response to a detected in-rush current. For example, the controller 108 can adjust a voltage based on a magnitude of an in-rush current, or can adjust a voltage by a pre-defined amount. The controller 108 can detect a cessation or continuation of the in-rush current following the adjustment. The controller 108 can increase the voltage of an output of the DC link 132 responsive to a detection of the in-rush current. For example, the controller 108 can detect an initial inrush current upon the connection of the battery 130 to the charger 100, and increase a voltage of an output of the DC link 132, such as by varying a control signal to the DAB circuit 104, or by increasing a voltage of the DC link input circuit 102. Subsequent to the increase in voltage, the controller 108 can detect that a DC link voltage is greater than the reference voltage for the DC link 132. For example, the in-rush current can continue subsequent to the initial adjustment, or a capacitor 118 can retain a charge in excess of the reference voltage. The controller can increase the voltage at the output of the DC link 132 responsive to the determination that a value of voltage at the DC link 132 is greater than the reference value for the DC link 132.

The controller 108 can determine that a voltage adjustment matches a voltage of the DC link 132 to the reference voltage. For example, an initial or subsequent adjustment of a voltage can be less than or equal to the reference voltage. The controller 108 can maintain or reduce the voltage incident to a detection that a voltage of the DC link 132 exceeds the reference voltage. For example, immediately following the connection of the battery 130 to the charger 100, the controller 108 can increase the voltage at an output of the charger 100, responsive to detection of the in-rush current. The detection of the in-rush current can be based on a voltage of the DC link input circuit 102 exceeding a reference voltage, as measured by a voltage sensor 110. Subsequent to the increase of the voltage, the controller 108 can determine that a DC link voltage is less than or equal to the reference voltage. The controller 108 can maintain the voltage at the output of the charger 100, responsive to the determination that the DC link voltage is less than or equal to the reference voltage. For example, the controller 108 can determine that the in-rush has been reduced, and that the battery voltage has been matched, slightly exceeded (e.g., to trickle charge), or otherwise exceeded (e.g., to charge the battery 130 at another rate).

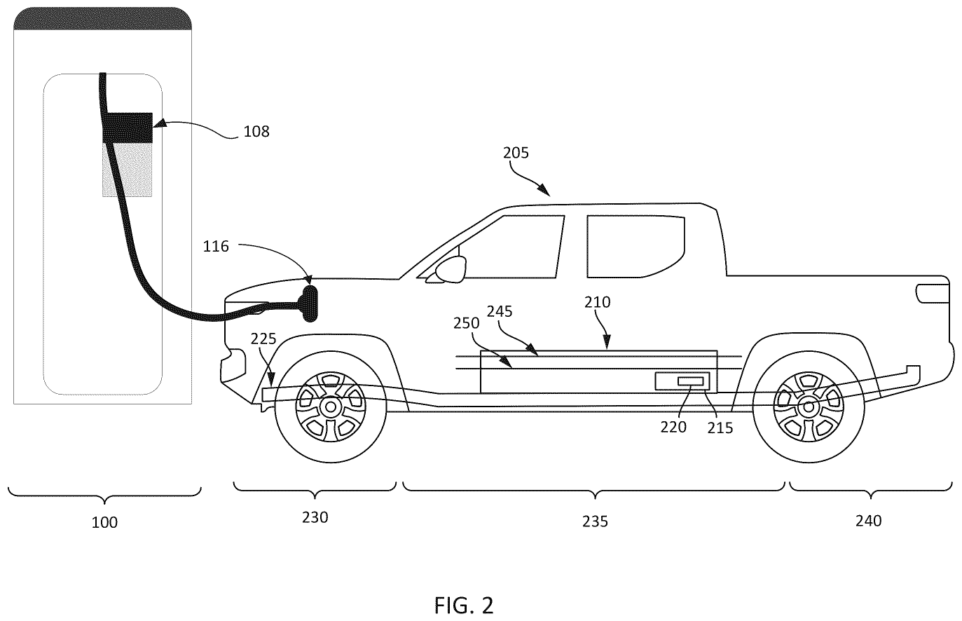

The battery 130 can be for an electric vehicle or a residential, commercial, or grid scale battery storage system. For example, the battery 130 can be for the electric vehicle of FIG. 2. The battery 130 can interface with various devices (e.g., the charger 100 can be a component of an electric vehicle, a charging station, or a battery storage system). The battery 130 can include a load controller including a user interface in communicative connection with the charger 100 (e.g., over a network). The battery 130 can include one or more components of a charger 100. For example, the charger 100 and battery 130 of FIG. 1 can each be electric vehicles having bidirectional charging, such that either electric vehicle can be a battery 130 or charger 100 according to the battery 130 state of charge or a selected direction of charge.

FIG. 2 depicts an example electric vehicle 205 coupled to a charger 100, in accordance with some aspects. Electric vehicles 205 can include electric trucks, electric sport utility vehicles (SUVs), electric delivery vans, electric automobiles, electric cars, electric motorcycles, electric scooters, electric passenger vehicles, electric passenger or commercial trucks, hybrid vehicles, or other vehicles such as sea or air transport vehicles, planes, helicopters, submarines, boats, or drones, among other possibilities. The battery pack 210 can also be used as an energy storage device to power a building, such as a residential home or commercial building. Electric vehicles 205 can be fully electric or partially electric (e.g., plug-in hybrid) and further, electric vehicles 205 can be fully autonomous, partially autonomous, or unmanned. Electric vehicles 205 can be human operated or non-autonomous. Electric vehicles 205 such as electric trucks or automobiles can include on-board battery packs 210, battery modules 215, or battery cells 220 to power the electric vehicles 205, any of which can be referred to as a battery 130 herein. The electric vehicle 205 can include a chassis 225 (e.g., a frame, internal frame, or support structure). The chassis 225 can support various components of the electric vehicle 205. For example, the chassis 225 can support an electric motor or an inverter. The chassis 225 can span a front portion 230 (e.g., a hood or bonnet portion), a body portion 235, and a rear portion 240 (e.g., a trunk, payload, or boot portion) of the electric vehicle 205.

The battery pack 210 can be installed or placed within the electric vehicle 205. For example, the battery pack 210 can be installed on the chassis 225 of the electric vehicle 205 within one or more of the front portion 230, the body portion 235, or the rear portion 240. The battery pack 210 can include or connect with at least one bus bar, e.g., a current collector element. For example, the first bus bar 245 and the second bus bar 250 can include electrically conductive material to connect or otherwise electrically couple the battery modules 215 or the battery cells 220 with other electrical components of the electric vehicle 205 to provide electrical power to or from various systems or components of the electric vehicle 205. The first bus bar 245 or the second bus bar 250 can be a conductor for the DC link input circuit 102 (e.g., a ground or supply portion thereof). For example, the first bus bar 245 or the second bus bar 250 can connect to a capacitor 118 of the DC link input circuit 102.

The load interface 116 can be communicatively or electrically connected to various elements of the electric vehicle 205 or the charger 100. For example, the electric vehicle 205 or the charger 100 can include at least the elements of FIG. 1, and the load interface 116 can communicate between the components to perform the methods disclosed herein. The controller 108 can adjust a charging of the electric vehicle 205, such as to match a voltage of the battery 130 of the electric vehicle 205 (e.g., to reduce an in-rush current below a threshold, such as a protection threshold, an operating threshold, or a threshold of detection). The controller 108 can adjust the voltage to a voltage offset from the battery 130 of the electric vehicle 205, such as to account for any conversions, diode drops, or resistive losses. The controller 108 can adjust the voltage to charge the electric vehicle 205.

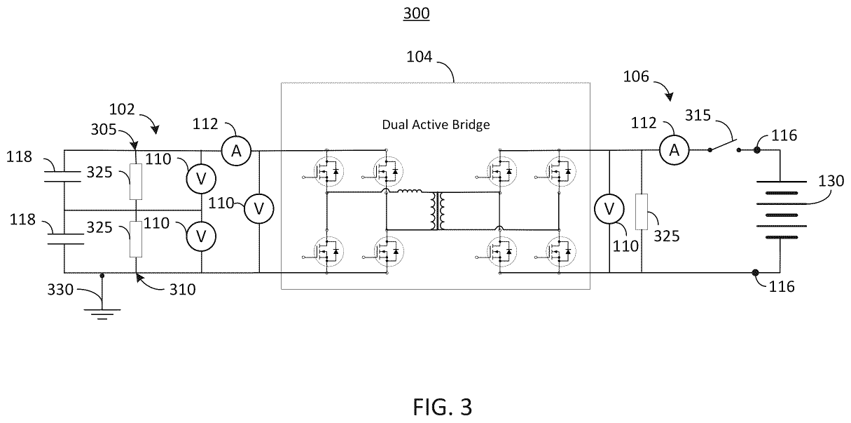

FIG. 3 depicts a circuit 300 for controlling reverse in-rush current, in accordance with some aspects. The circuit 300 can be part of the charger 100 depicted in FIG. 1. The circuit 300 can include one or more components or functionality of the charger 100 depicted in FIG. 1. For example, the circuit 300 can include an output DC link circuit 106 for an electric vehicle 205 or an energy storage device. The circuit 300 can include a bidirectional or unidirectional charge device. The circuit 300 can include a DC to DC converter, or AC to DC converter. For example, the circuit 300 can include a DAB circuit 104 to provide a charging output for a battery 130. The battery 130 can be connected to the output of the charger 100 via a load interface 116 such as a plug or receptacle. A switchable connection 315 such as a relay or contactor can selectively connect the output DC link circuit 106 to the battery 130 of the electric vehicle 205. The charger 100 or the electric vehicle 205 can include various contactors, blocking diodes, or filters. For example, the switchable connection 315 can connect to the battery 130 responsive to determining the presence of the battery 130.

The energy provided to the battery 130 can be sourced from a DC link input circuit 102. The DC link input circuit 102 can be an intermediate stage of energy sourced from a DC or AC source such as an energy storage device or electrical grid. The DC link input circuit 102 can include two capacitors 118 in series with one another, with one of the capacitors 118 connected to ground 330.

The voltage of the DC link input circuit 102 can vary from the voltage of the output DC link circuit 106. For example, the DAB circuit 104 can include a transformer having a gain, including a non-unitary gain. For example, the DAB circuit 104 can have a gain of 0.5, 1, or 2. The DAB circuit 104 can isolate the DC link input circuit 102 from the output DC link circuit 106 such that a ground 330 of the DC link input circuit is not shared with the output DC link circuit 106. One or more resistors 325 can be a part of a voltage sensor 110 or current sensor 112, or can draw current to maintain a stability of the circuit 300 (e.g., according to a minimum on time of a circuit). The resistors 325, or various other components of the circuit 300 can be omitted, substituted, or added. For example, various DC to DC converters can be substituted for the DAB circuit 104, or a capacitor 118 can be included at the output of the charger 100 (e.g., as a part of a filtering or protection component of the circuit 300). The DC link input circuit 102 can comprise two legs, such as a positive leg 305 and a negative leg 310 with respect to a center tap. The negative leg 310 can include a ground 330 for the circuit 300 such that the two legs sum to create a DC link input circuit 102 voltage. A voltage sensor 110 can detect the voltage of either or both legs, or the combination of both legs. A current sensor 112 can detect a current of the output DC link circuit 106, the DC link input circuit 102, or a leg thereof.

The controller 108 can control the gate of switching transistors of the DAB circuit 104 to control a voltage or current (e.g., a direction of current flow). The controller 108 can adjust a voltage of the output of the charger 100 by adjusting the on-time of the transistors of the DAB circuit 104 by increasing a phase shift of a control signal for the gates of the transistors of the DAB circuit 104 to raise the output voltage of the DAB circuit 104 (e.g., the output DC link circuit 106 voltage) above the voltage of the battery 130 to prevent the in-rush current. The controller 108 can adjust a voltage of the DC link input circuit 102, such as by adjusting an operation of an inverter or converter (not depicted) disposed between the input of the DC link input circuit 102 and an energy source for the DC link input circuit 102, such as an energy grid. For example, the controller 108 can adjust the current delivered by the output DC link circuit 106 or a voltage of the DC link input circuit 102.

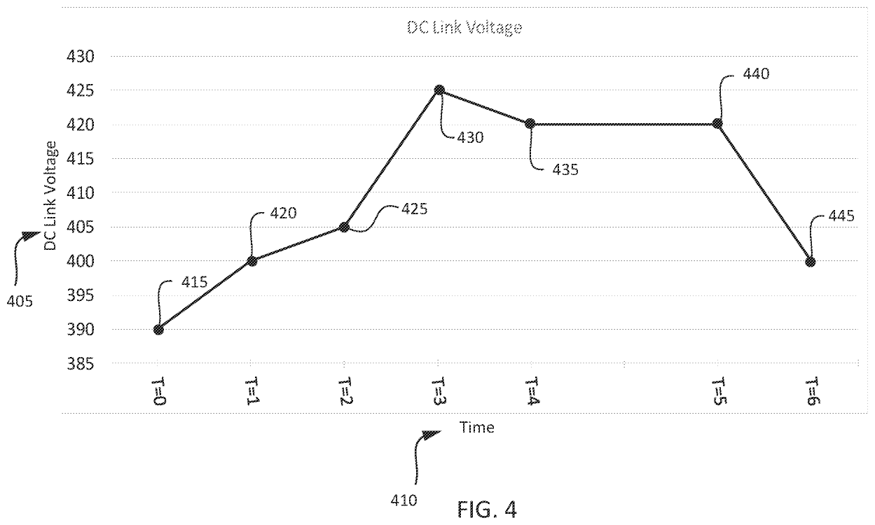

FIG. 4 depicts example voltages of a DC link charging an electric vehicle 205, in accordance with some aspects. The controller 108 can adjust the DC link voltage 405 over a time axis 410. The time axis 410 and other figures of the present disclosure are not drawn to scale. The controller 108 can set the DC link voltage 405 to 390 volts at a first time 415. The controller 108 can establish the DC link voltage 405 in response to a predicted battery voltage. The battery voltage can be based on a voltage of other batteries (e.g., an average, minimum, or percentile), a nominal voltage, or load data 122 for the battery 130. For example, the controller 108 receive load data 122 via the load interface 116.

At a second time 420, the DC link voltage 405 can increase to 400 volts. The voltage increase can be incident to the connection of the battery 130. For example, the connection of the battery 130 can charge the capacitors 118 of the DC link input circuit 102 at a rate based on the capacity thereof, and the current sourced from the battery 130. At a third time 425, the controller 108 can detect the voltage rise via a voltage sensor 110 and, responsive to the detected voltage rise, increase the DC link voltage 405. For example, the controller 108 can increase a DC link voltage 405 to 405 volts to reduce, eliminate, or reverse a current flow between the battery 130 and the charger 100. The third time 425 can be within one second of the second time 420. For example, the third time 425 can be within 300 ms, 100 ms, or 50 ms of the second time 420. The controller 108 can select a voltage to match the battery 130 or to cause a current to flow to the battery 130 (such as a trickle charge).

At a fourth time 430, the controller 108 can increase the DC link voltage 405 to a charging voltage. For example, the controller 108 can increase the DC link voltage 405 to 425 volts. The controller 108 can increase or decrease the DC link voltage 405 (or the voltage of the output DC link circuit 106) to maintain or adjust the charge rate. For example, the controller 108 can adjust the voltage based on a current sensor 112 for the output DC link circuit 106. The controller 108 can adjust the voltage at a time greater than the difference between the second time 420 and the third time 425. The controller 108 can make any number of adjustments according to a charging profile for a battery 130, such as the depicted adjustments of the fifth time 435 or sixth time 440 during charging and return to a voltage to match or trickle charge the battery 130 at a seventh time 445.

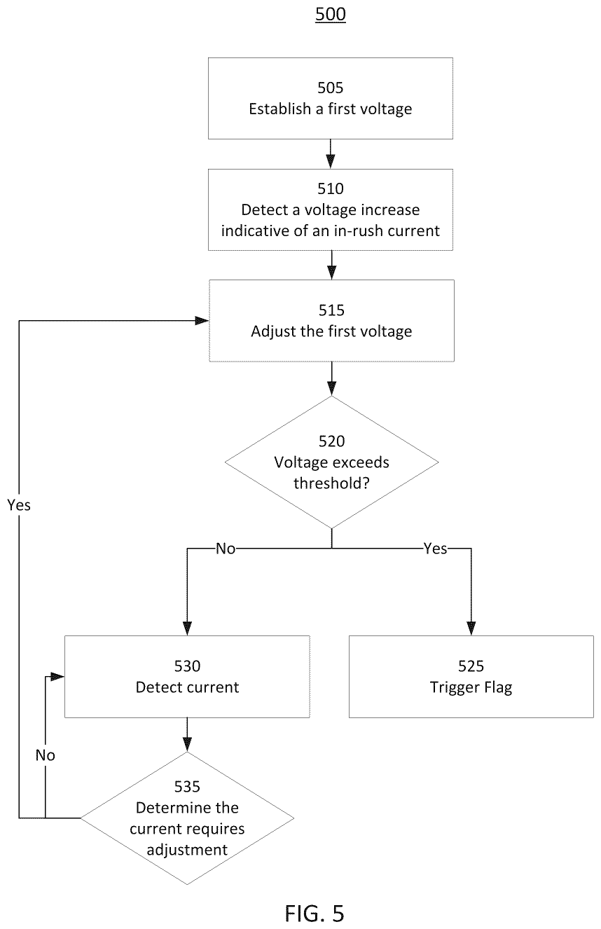

FIG. 5 depicts a flow diagram for a method 500 to deliver power to an energy storage device, such as a battery 130 of an electric vehicle 205, in accordance with some aspects. The method 500 can be performed by one or more components or systems depicted in FIG. 1-3 or 7. At ACT 505, a controller 108 can measure, determine, detect or otherwise identify a first voltage. At ACT 510, the controller 108 can detect an increase of the first voltage indicative of an in-rush current. At ACT 515, the controller 108 can adjust the first voltage. At ACT 520, the controller 108 can determine whether the first voltage exceeds a threshold. At ACT 525, the controller 108 can trigger a flag, responsive to the threshold. At ACT 530, the controller 108 can detect a current. At ACT 535, the controller 108 can determine whether the current requires adjustment.

At ACT 505, a controller 108 can establish a first voltage. For example, the controller 108 can establish the first voltage for a DC link input circuit 102, or an output DC link circuit 106. The controller 108 can base the voltage on an expected voltage level of the battery 130. For example, the controller 108 can establish the voltage to match a battery voltage or to cause the battery 130 to be charged by the charger 100 at a pre-charge rate less than a charge rate (e.g., a trickle charge). The controller 108 can establish the voltage by conveying a control signal to a voltage control component 114. At ACT 510, the controller 108 can detect an increase of the first voltage indicative of an in-rush current. For example, the first voltage can rise incident to a transfer of energy from the battery 130 to a capacitor 118 of the charger 100. The controller can detect the increase in the first voltage based on a voltage sensor 110, such as a voltage sensor 110 of a DC link input circuit 102, separated from an output DC link circuit 106 by a DAB circuit 104 including an isolating component such as a transformer.

At ACT 515, the controller 108 can adjust the first voltage. For example, the controller 108 can increase a voltage to reduce, eliminate, or reverse an inflow of current. The controller 108 can increase the voltage of an output of the DC link responsive to the detection of the first voltage at ACT 510. The adjustment of the voltage can be iterative, such that various adjustments can be made periodically to achieve a desired balance between the DC link input circuit 102, output DC link circuit 106, or battery 130. The controller 108 can adjust the voltage via the voltage control component 114.

At ACT 520, the controller 108 can determine whether the first voltage exceeds a threshold. For example, the threshold can be or include a temporal component or a voltage component. For example, the threshold can be a time threshold (e.g., a duration) for the voltage to exceed the reference voltage, or be offset therefrom (e.g., exceed the reference voltage by more than a fixed offset or percent). The threshold can include an absolute maximum voltage, current, or offset from a reference voltage. For example, a voltage exceeding a reference voltage by one-hundred volts can exceed a threshold without regard to a time. Responsive to determining the threshold has been met or exceeded, the method 500 can proceed to ACT 525. Responsive to determining the threshold has not been met or exceeded, the method 500 can proceed to ACT 530.

At ACT 525, the controller 108 can trigger a flag, responsive to the threshold being met. For example, the flag can indicate a condition of the charger 100 or energy storage device (e.g., to alert a user, maintenance staff, or other associated party). For example, the controller 108 can convey the flag over a network to convey a device status. The controller 108 can generate the flag as indicative of a state of a sensor. For example, the flag can indicate that a voltage sensor 110 or current sensor 112 is reporting values which are not indicative of the expected operation of a corresponding device. For example, the flag can indicate that the sensor is offline, disabled, non-operational, or out-of-calibration. The controller 108 can proceed to charging (or continue charging) based on an alternative sensor responsive to such a determination, or can adjust (e.g., lower) a charge rate. The controller 108 can terminate charging or proceed to a non-operational state incident to generating the flag (e.g., can open a contactor).

At ACT 530, the controller 108 can detect a current. For example, the controller 108 can poll or otherwise receive an indication of a current provided from the output DC link circuit 106 from a current sensor 112, different from the voltage sensor 510 of, for example, ACT 510. The current can be a charging current for the battery 130 of an electric vehicle 205. At ACT 535. the controller 108 can determine whether the current requires adjustment. For example, the controller 108 can monitor a voltage of a DC link input circuit 102 or a current output from the charger 100 to a battery 130; the adjustment can be an adjustment to the voltage to cause an adjustment to an output current of the charger 100. Responsive to a determination that an adjustment is needed, the method 500 can proceed to ACT 515. Responsive to a determination that no adjustment is needed, the method 500 can proceed to ACT 530.

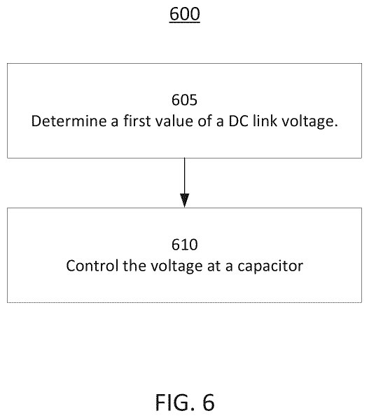

FIG. 6 depicts a flow diagram for a method 600 to charge a battery 130, in accordance with some aspects. The method 600 can be performed by one or more components or systems depicted in FIG. 1-3 or 7. At ACT 605, a controller 108 can determine a first value of a DC link input circuit 102 voltage. At ACT 610, the controller 108 can control the voltage of a capacitor 118, responsive to the comparison of a voltage of the DC link input circuit 102 with a reference voltage for the DC link input circuit 102.

At ACT 605, a controller 108 can determine a first value of a DC link input circuit 102 voltage. For example the controller 108 can receive the value from a voltage sensor 110 disposed across one or more legs of a DC link input circuit 102. The controller 108 can determine an output voltage for the charger 100 based on the voltage received from the voltage sensor 110. The controller 108 can be a controller 108 of a charger 100 configured to output power to a battery 130 via a capacitor 118, such as a capacitor 118 of the DC link input circuit 102 or output DC link circuit 106.

At ACT 610, the controller 108 can control the voltage of a capacitor 118, responsive to the comparison of a voltage of the DC link input circuit 102 with a reference voltage for the DC link input circuit 102. For example, the controller 108 can convey a signal to a voltage control component 114 for a DC to DC converter or an AC to DC converter. For example, the signal can be a switching signal to a transistor or can cause a switching signal to be conveyed to a transistor of a DC to DC converter or AC to DC converter.

FIG. 7 is a block diagram illustrating an architecture for a computer system 700 that can be employed to implement elements of the systems and methods described and illustrated herein. The computer system or computing device 700 can include or be used to implement a charger 100 or its components, such as the charger 100 and components thereof. The computing system 700 includes at least one bus 705 or other communication component for communicating information (e.g., within the charger 100 or between the charger 100 and the battery 130) and at least one processor 710 or processing circuit coupled to the bus 705 for processing information. The computing system 700 can also include one or more processors 710 or processing circuits coupled to the bus for processing information. The computing system 700 also includes at least one main memory 715, such as a random access memory (RAM) or other dynamic storage device, coupled to the bus 705 for storing information, and instructions to be executed by the processor 710. The main memory 715 can be used for storing information during execution of instructions by the processor 710. The computing system 700 may further include at least one read only memory (ROM) 720 or other static storage device coupled to the bus 705 for storing static information and instructions for the processor 710. A storage device 725, such as a solid state device, magnetic disk or optical disk, can be coupled to the bus 705 to persistently store information and instructions.

The computing system 700 may be coupled via the bus 705 to a display 735, such as a liquid crystal display, or active matrix display, for displaying information to a user such as a driver of the electric vehicle 205 or other user. An input device 730, such as a keyboard or voice interface may be coupled to the bus 705 for communicating information and commands to the processor 710. The input device 730 can include a touch screen display 735. The input device 730 can also include a frequency selection, power selection, or charging time selection, for communicating direction information and command selections to the processor 710 and for controlling cursor movement on the display 735.

The processes, systems and methods described herein can be implemented by the computing system 700 in response to the processor 710 executing an arrangement of instructions contained in main memory 715. Such instructions can be read into main memory 715 from another computer-readable medium, such as the storage device 725. Execution of the arrangement of instructions contained in main memory 715 causes the computing system 700 to perform the illustrative processes described herein. One or more processors in a multi-processing arrangement may also be employed to execute the instructions contained in main memory 715. Hard-wired circuitry can be used in place of or in combination with software instructions together with the systems and methods described herein. Systems and methods described herein are not limited to any specific combination of hardware circuitry and software.

Although an example computing system has been described in FIG. 7, the subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C #, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

For example, descriptions of positive and negative electrical characteristics may be reversed. For example, the controller 108 can increase rather than decrease a voltage to cause charging in a reverse direction. Elements described as negative elements can instead be configured as positive elements and elements described as positive elements can instead by configured as negative elements. For example, elements described as having first polarity can instead have a second polarity, and elements described as having a second polarity can instead have a first polarity. Further relative parallel, perpendicular, vertical or other positioning or orientation descriptions include variations within +/−10% or +/−10 degrees of pure vertical, parallel or perpendicular positioning. References to “approximately,” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. A system, comprising:
a controller configured to:
determine a first value of voltage at an input of a direct current (“DC”) link in a charger configured to output power to a battery of an electric vehicle; and
detect, responsive to the first value of voltage at the input of the DC link being greater than a reference value of voltage established for the DC link, an in-rush current from the battery to the charger.

2. The system of claim 1, comprising:
a capacitor located at an output of the DC link; and
the controller configured to increase, responsive to detection of the in-rush current, voltage at the output of the DC link.

3. The system of claim 1, comprising the controller to:
determine a duration for which the first value of voltage at the input of the DC link is greater than the reference value of voltage established for the input of the DC link; and
trigger a flag responsive to the duration greater than or equal to a threshold.

4. The system of claim 1, comprising the controller to:
determine a duration for which the first value of voltage at the input of the DC link is greater than the reference value of voltage established for the input of the DC link; and
terminate current flow from the charger to the battery responsive to the duration greater than or equal to a threshold.

5. The system of claim 1, comprising the controller to:
determine a duration for which the first value of voltage at the input of the DC link is greater than the reference value of voltage established for the input of the DC link; and
identify, based on the duration greater than or equal to a threshold, a state of a current sensor that measures current between the charger and the battery.

6. The system of claim 1, comprising the controller to:
increase, responsive to detection of the in-rush current, the voltage at an output of the DC link;
determine, subsequent to the increase of the voltage at the output, that a second value of voltage at the input of the DC link is greater than the reference value of voltage established for the input of the DC link; and
increase, responsive to the determination that the second value of voltage at the input of the DC link is greater than the reference value of voltage established for the input of the DC link, the voltage at the output of the DC link to a third value.

7. The system of claim 1, comprising the controller to:
increase, responsive to detection of the in-rush current, the voltage at an output of the charger to a second value;
determine, subsequent to the increase of the voltage at the output to the second value, that a third value of voltage at the input of the DC link is less than or equal to the reference value of voltage established for the input of the DC link; and
maintain, responsive to the determination that the third value of voltage at the input of the DC link is less than or equal to the reference value of voltage for the input of the DC link, the voltage at the output at the second value.

8. A system, comprising:
a controller configured to:
determine a first value of voltage at an input of a direct current (“DC”) link in a charger configured to output power to a battery via a capacitor; and
control, responsive to a comparison of the first value of voltage at the input of the DC link with a reference value of voltage established for the input of the DC link, voltage at the capacitor.

9. The system of claim 8, comprising the controller to:
determine that the first value of voltage at the input of the DC link is greater than the reference value of voltage established for the input of the DC link; and
provide, responsive to the determination that the first value of voltage at the input of the DC link is greater than the reference value of voltage for the input of the DC link, an indication of in-rush current.

10. The system of claim 8, comprising the controller to:
determine that the first value of voltage at the input of the DC link is greater than the reference value of voltage established for the input of the DC link; and
increase, responsive to the determination that the first value of voltage at the input of the DC link is greater than the reference value of voltage for the input of the DC link, the voltage at the capacitor to a second value.

11. The system of claim 8, comprising the controller to:
determine that the first value of voltage at the input of the DC link is less than or equal to the reference value of voltage established for the input of the DC link; and
maintain, responsive to the determination that the first value of voltage at the input of the DC link is less than or equal to the reference value of voltage for the input of the DC link, the voltage at the capacitor at a same value.

12. The system of claim 8, comprising the controller to:
determine a duration for which the first value of voltage at the input of the DC link is greater than the reference value of voltage established for the input of the DC link; and
trigger a flag responsive to the duration greater than or equal to a threshold.

13. The system of claim 8, comprising the controller to:
determine a duration for which the first value of voltage at the input of the DC link is greater than the reference value of voltage established for the input of the DC link; and
terminate current flow from the charger to the battery responsive to the duration greater than or equal to a threshold.

14. The system of claim 8, comprising the controller to:
determine a duration for which the first value of voltage at the input of the DC link is greater than the reference value of voltage established for the input of the DC link; and
identify, based on the duration greater than or equal to a threshold, a state of a current sensor that measures current between the charger and the battery.

15. The system of claim 8, comprising the controller to:
increase, responsive to the comparison of the first value of voltage at the input of the DC link with the reference value of voltage established for the input of the DC link, the voltage at the capacitor to a second value;
determine, subsequent to the increase of the voltage at the capacitor to the second value, that a third value of voltage at the input of the DC link is greater than the reference value of voltage established for the input of the DC link; and
increase, responsive to the determination that the third value of voltage at the input of the DC link is greater than the reference value of voltage established for the input of the DC link, the voltage at the capacitor to a fourth value greater than the second value.

16. The system of claim 8, comprising:
the controller to control, responsive to the comparison of the first value of voltage at the input of the DC link with the reference value of voltage established for the input of the DC link, the voltage at the capacitor to match a second value of voltage at the battery.

17. A method, comprising:
determining, by a controller, a first value of voltage at an input of a direct current (“DC”) link in a charger configured to output power to a battery via a capacitor; and
controlling, by the controller, responsive to a comparison of the first value of voltage at the input of the DC link with a reference value of voltage established for the input of the DC link, voltage at the capacitor.

18. The method of claim 17, comprising:
determining, by the controller, that the first value of voltage at the input of the DC link is greater than the reference value of voltage established for the input of the DC link; and
providing, by the controller, responsive to the determination that the first value of voltage at the input of the DC link is greater than the reference value of voltage for the input of the DC link, an indication of in-rush current.

19. The method of claim 17, comprising:
determining, by the controller, that the first value of voltage at the input of the DC link is greater than the reference value of voltage established for the input of the DC link; and
increase, responsive to the determination that the first value of voltage at the input of the DC link is greater than the reference value of voltage for the input of the DC link, the voltage at the capacitor to a second value.

20. The method of claim 17, comprising:
determining, by the controller, that the first value of voltage at the input of the DC link is less than or equal to the reference value of voltage established for the input of the DC link; and
maintaining, by the controller, responsive to the determination that the first value of voltage at the input of the DC link is less than or equal to the reference value of voltage for the input of the DC link, the voltage at the capacitor at a same value.
